(19) United States
(12) Patent Application Publication
(10) Pub. No.: US 2013/0108893 A1
(43) Pub. Date: May 2, 2013

(54) ELECTRONIC DEVICE WITH THERMOELECTRIC CELL MODULE

(71) Applicants: FA-GUANG SHI, Shenzhen City (CN); JIAN-ZHOU ZHAO, Shenzhen City (CN); YAN LIANG, Shenzhen City (CN)

(72) Inventors: FA-GUANG SHI, Shenzhen City (CN); JIAN-ZHOU ZHAO, Shenzhen City (CN); YAN LIANG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/368,612

(22) Filed: Feb. 8, 2012

(30) Foreign Application Priority Data
Oct. 31, 2011 (CN) 201110337325.5

(51) Int. Cl. H01M 14/00; H01L 35/04; H01L 35/32; G06F 1/16

(52) U.S. Cl. 429/7; 361/679.02; 136/229; 136/225; 136/201

(57) ABSTRACT

An electronic device includes a bottom housing, a heat-generating component placed on the bottom housing, and a thermoelectric cell module placed on the bottom housing and corresponding to the heat-generating component. The thermoelectric cell module includes a first thermoelectric sheet sensing a temperature of the heat-generating component, a second thermoelectric sheet sensing a temperature of the bottom housing, and a conductive member electrically connecting the first thermoelectric sheet and the second thermoelectric sheet.

### BACKGROUND

1. Technical Field

The present disclosure relates generally to electronic devices, especially, to an electronic device with a thermoelectric cell module.

2. Description of Related Art

During usage of an electronic device, electronic components, such as battery or CPU, generate heat. If the heat cannot be dissipated effectively in time, usage lifespan of the electronic components and a processing speed of the electronic device may be affected negatively. Additionally, during usage of the electronic device, electrical energy is needed, while the heat generated by the electronic components is not utilized effectively. Thus, energy is wasted.

Therefore, there is room for improvement within the art.

### BRIEF DESCRIPTION OF THE DRAWINGS

The elements in the drawings are not necessarily drawn to scale, the emphasis instead placed upon clearly illustrating the principles of the present disclosure. Moreover, in the drawings, like reference numerals designate corresponding parts throughout the several views.

FIG. 1 is an assembled, isometric view of an embodiment of an electronic device without a top cover and a display module.

FIG. 2 is an exploded, isometric view of the electronic device of FIG. 1.

FIG. 3 is similar to FIG. 1, but viewed from another aspect without a central processing unit.

FIG. 4 is a cross-sectional view of FIG. 1, taken along line IV-IV.

FIG. 5 is an enlarged view of circular part V of FIG. 4.

### DETAILED DESCRIPTION

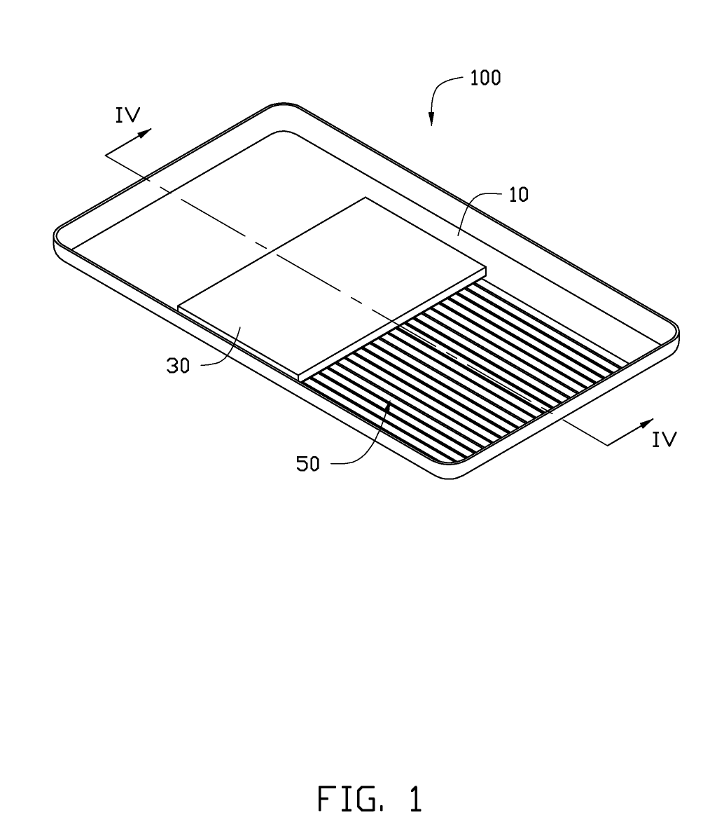

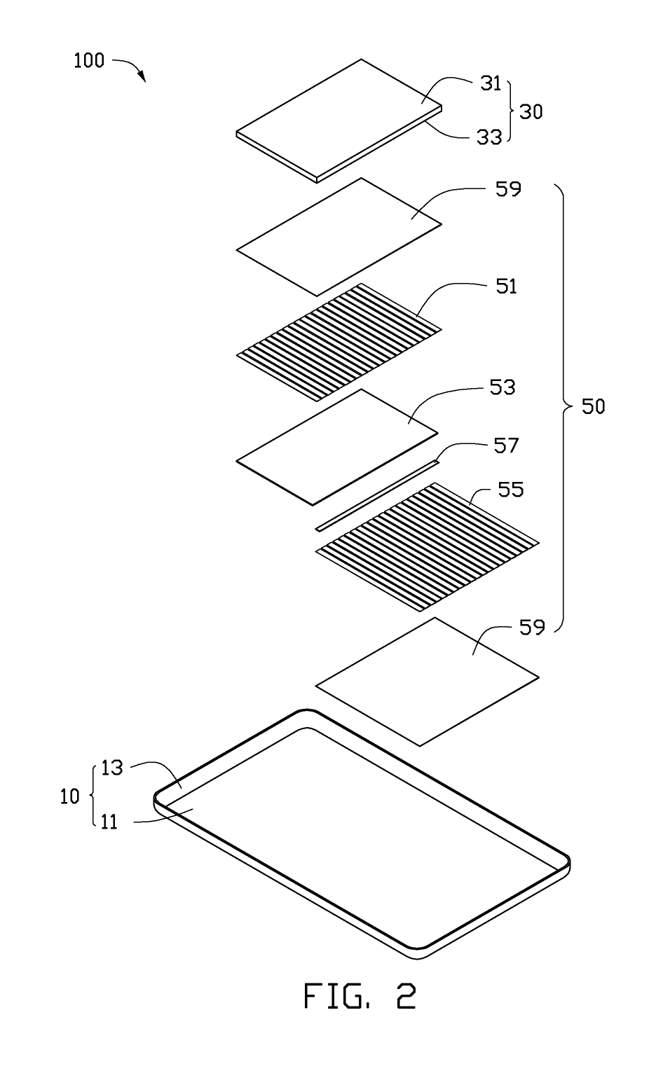

Referring to FIGS. 1 and 2, an embodiment of an electronic device 100 includes a bottom housing 10, a central processing unit (CPU) 30, and a thermoelectric cell module 50. The CPU 30 and the thermoelectric cell module 50 are securely placed on the bottom housing 10. The electronic device 100 can be a tablet computer, a mobile phone, a liquid crystal display, or a digital photo album. The electronic device 100 includes other various functional modules, such as a top cover (not shown) or a display module (not shown). However, for simplicity, only the components related to the thermoelectric cell module 50 are described herein.

The bottom housing 10 includes a base 11 and a peripheral wall 13 extending from a periphery of the base 11. The base 11 is substantially rectangular. The base 11 and the peripheral wall 13 cooperatively form a receiving space (not labeled) for receiving various functional modules.

The CPU 30 is mounted substantially on a center region of the base 11. The CPU 30 includes a first surface 31 and a second surface 33 opposite to the first surface 31. The first surface 31 is away from the bottom housing 10, and the second surface 33 is adjacent to the bottom housing 10. During usage of the electronic device 100, the CPU 30 will generate heat. Thus, a temperature of the CPU 30 is higher than that at a location area of the base 11 deviated or away from the CPU 30.

The thermoelectric cell module 50 includes a first thermoelectric sheet 51, a heat resisting sheet 53, a second thermoelectric sheet 55, a conductive member 57, and two insulation sheets 59.

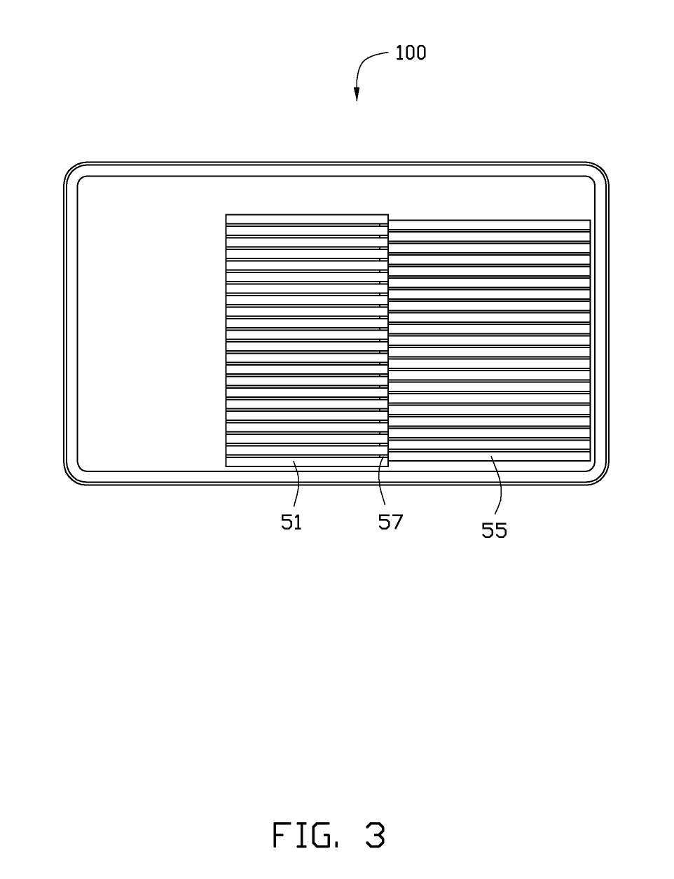

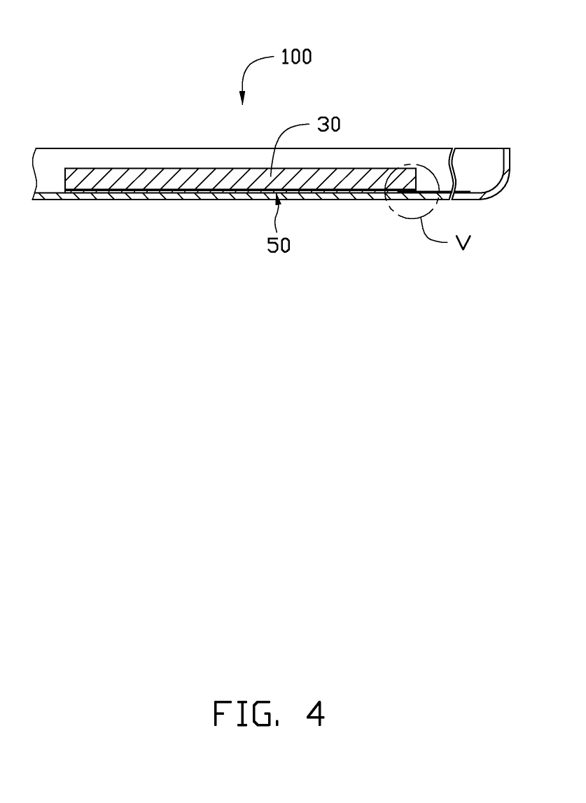

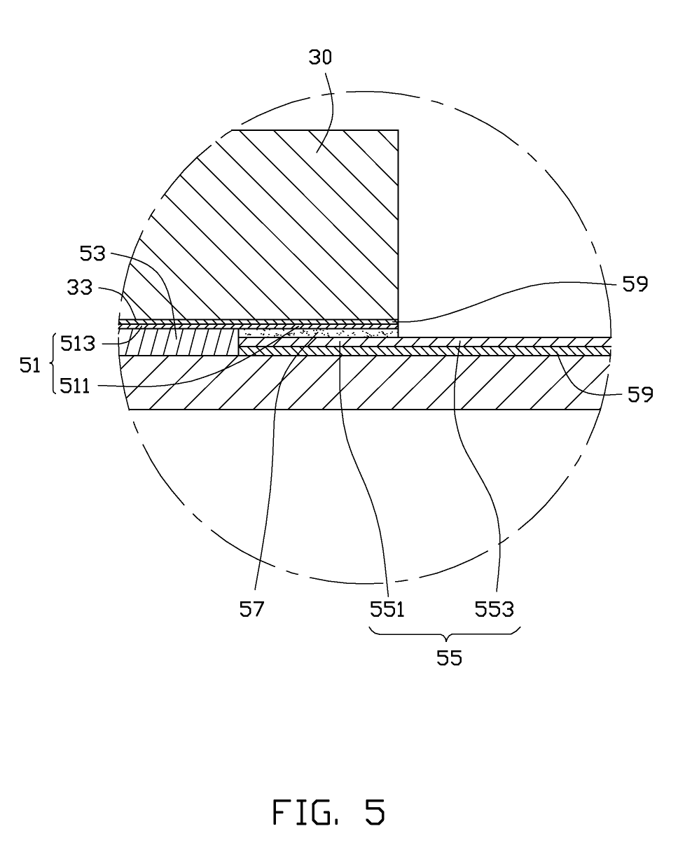

Also referring to FIGS. 3 through 5, the first thermoelectric sheet 51 is placed below the second surface 33, for sensing the temperature of the CPU 30. The first thermoelectric sheet 51 includes a first connection end 511 and a body 513 extending from the first connection end 511.

The heat resisting sheet 53 is sandwiched between the body 513 and the base 11, for resisting the heat generated by the CPU 30 from being dissipated.

The second thermoelectric sheet 55 is placed on the base 11, for sensing the temperature at the location area of the base 11 deviated or away from the CPU 30. The second thermoelectric sheet 55 includes a second connection end 551 and a body 553 extending from the second connection end 551. The second connection end 551 is adjacent to the heat resisting sheet 53, and is below the first connection end 511 of the first thermoelectric sheet 51. The body 553 is deviated or away from the CPU 30.

The conductive member 57 is sandwiched between the first connection end 511 and the second connection end 551, for electrically connecting the first connection end 511 and the second connection end 551. The temperature of the CPU 30 is higher than that at the location area of the base 11 away or deviated from the CPU 30, and a temperature difference is generated between the first thermoelectric sheet 51 and the second thermoelectric sheet 55, such that the first thermoelectric sheet 51 and the second thermoelectric sheet 55 cooperatively form a thermoelectric cell.

One of the insulation sheets 59 is sandwiched between the first thermoelectric sheet 51 and the second surface 33 of the CPU 30 to insulate the first thermoelectric sheet 51 from the CPU 30. The other insulation sheet 59 is sandwiched between the second thermoelectric sheet 55 and the base 11 to insulate the second thermoelectric sheet 55 from the base 11.

In an illustrated embodiment, a quantity of the first thermoelectric sheet 51 is more than one. Each first thermoelectric sheet 51 is substantially strip-like, and is made of antimony telluride (Sb₂Te₃) P-type semi-conductive thermoelectric materials. A plurality of the first thermoelectric sheets 51 are placed in alignment. A quantity of the second thermoelectric sheet 55 is the same as that of the first thermoelectric sheets 51, correspondingly. Each second thermoelectric sheet 55 is substantially strip-like, and is made of bismuth telluride (Bi₂Te₃) N-type semi-conductive thermoelectric materials. The second thermoelectric sheets 55 are placed in alignment beside the first thermoelectric sheets 51, and each second thermoelectric sheet 55 is partially stacked with a first thermoelectric sheet 51 correspondingly. The conductive member 57 is an anisotropic conductive adhesive film, and is conductive only in a direction perpendicular to the first thermoelectric sheet 51 or the second thermoelectric sheet 55. Thus, a plurality of the thermoelectric cells formed by the first thermoelectric sheets 51 and the second thermoelectric sheets 55 are electrically connected in series arrangement, to improve an output voltage of the thermoelectric cell module 50.

In the illustrated embodiment, the first thermoelectric sheet 51 and the second thermoelectric sheet 55 are adhered respectively to the insulation sheets 59 by adhesive. The first thermoelectric sheet 51 and the second thermoelectric sheet 55 can be replaced by a first thermoelectric film and a second thermoelectric film instead. The first thermoelectric film and the second thermoelectric film can be formed on the insulation sheets 59 by a plurality of methods, such as magnetron sputtering, vacuum deposition, or pulsed laser deposition. The heat resisting sheet 53 is adhered to the base 11 by adhesive. The heat resisting sheet 53 can be omitted, and in that case, a heat insulation film instead can be coated on the base 11, and the second thermoelectric sheet 55 is adhered to the base 11 coated with the heat insulation film. The insulation sheets 59 can be omitted. In that case, the second surface 33 of the CPU 30 is made of an insulation material or coated with an insulation material, and the inside of the base 11 is formed with an insulation layer, the first thermoelectric sheet 51 is directly adhered to the second surface 33, and the second thermoelectric sheet 55 is directly adhered to the base 11.

The first thermoelectric sheet 51 can be made of one of P-type semi-conductive thermoelectric materials or N-type semi-conductive thermoelectric materials. Meanwhile, the second thermoelectric sheet 55 can be made of the other one of the P-type semi-conductive thermoelectric materials or N-type semi-conductive thermoelectric materials, correspondingly.

The thermoelectric cell module 50 can be placed in a location correspondingly to other heat-generating components of the electronic device 100, such as battery, so that more than one thermoelectric cells can be formed because of temperature differences found between other heat-generating components and the base 11.

The thermoelectric cell module 50 is placed inside the electronic device 100, and the thermoelectric cell is formed by utilizing a temperature difference between different components of the electronic device 100, such that the heat generated by the heat-generating components, such as the CPU 30 or the battery, is effectively utilized, and converted into electrical energy. Thus, energy is saved, and the heat of the electronic device 100 can be effectively dissipated.

It is to be understood, however, that even through numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. An electronic device, comprising:
a bottom housing;
a heat-generating component placed on the bottom housing;
a thermoelectric cell module placed on the bottom housing and corresponding to the heat-generating component, the thermoelectric cell module comprising:
a first thermoelectric sheet sensing a temperature of the heat-generating component;
a second thermoelectric sheet sensing a temperature of the bottom housing; and
a conductive member electrically connecting the first thermoelectric sheet and the second thermoelectric sheet.

2. The electronic device of claim 1, wherein the heat-generating component comprises a central processing unit.

3. The electronic device of claim 2, wherein the central processing unit comprises a first surface away from the bottom housing, and a second surface opposite to the first surface and adjacent to the bottom housing, the first thermoelectric sheet is placed below the second surface, and the second thermoelectric sheet is placed on a location area of the bottom housing deviated from the central processing unit.

4. The electronic device of claim 1, wherein a quantity of the first thermoelectric sheet is more than one, a quantity of the second thermoelectric sheet is the same as the quantity of the first thermoelectric sheet, the first thermoelectric sheets are placed in alignment, the second thermoelectric sheets are placed in alignment beside the first thermoelectric sheets, and each second thermoelectric sheet is partially stacked with a first thermoelectric sheet correspondingly.

5. The electronic device of claim 4, wherein the conductive member is made of an anisotropic conductive adhesive film, and is conductive only in a direction perpendicular to the first thermoelectric sheet or the second thermoelectric sheet.

6. The electronic device of claim 4, wherein each first thermoelectric sheet comprises a first connection end, each second thermoelectric sheet comprises a second connection end and a body extending from the second connection end, the second connection end is placed below the first connection end, the body is deviated from the central processing unit, and the conductive member is sandwiched between the first connection end and the second connection end.

7. The electronic device of claim 6, wherein each first thermoelectric sheet further comprises a body extending from the first connection end, the thermoelectric cell module further comprises a heat resisting sheet, and the heat resisting sheet is sandwiched between the body of the first thermoelectric sheet and the bottom housing, and is adjacent to the second connection end.

8. The electronic device of claim 1, wherein the first thermoelectric sheet is made of one of P-type semi-conductive thermoelectric materials or N-type semi-conductive thermoelectric materials and the second thermoelectric sheet is made of the other one of the P-type semi-conductive thermoelectric materials or N-type semi-conductive thermoelectric materials.

9. The electronic device of claim 8, wherein the first thermoelectric sheet is made of antimony telluride P-type semi-conductive thermoelectric materials, and the second thermoelectric sheet is made of bismuth telluride N-type semi-conductive thermoelectric materials.

10. The electronic device of claim 1, wherein the heat-generating component comprises a battery.

11. An electronic device, comprising:
a bottom housing;
a heat-generating component placed on the bottom housing, the heat-generating component comprising a central processing unit;
a thermoelectric cell module placed on the bottom housing and corresponding to the heat-generating component, the thermoelectric cell module comprising:
a first thermoelectric sheet sensing a temperature of the heat-generating component, wherein the first thermoelectric sheet is made of one of P-type semi-conductive thermoelectric materials or N-type semi-conductive thermoelectric materials;
a second thermoelectric sheet sensing a temperature of the bottom housing, wherein the second thermoelectric sheet is made of the other one of the P-type semi-conductive thermoelectric materials or N-type semi-conductive thermoelectric material; and
a conductive member electrically connecting the first thermoelectric sheet and the second thermoelectric sheet.

12. The electronic device of claim 11, wherein the central processing unit comprises a first surface away from the bottom housing, and a second surface opposite to the first surface and adjacent to the bottom housing, the first thermoelectric sheet is placed below the second surface, and the second thermoelectric sheet is placed on a location area of the bottom housing deviated from the central processing unit.

13. The electronic device of claim 11, wherein a quantity of the first thermoelectric sheet is more than one, a quantity of the second thermoelectric sheet is the same as the quantity of the first thermoelectric sheet, the first thermoelectric sheets are placed in alignment, the second thermoelectric sheets are placed in alignment beside the first thermoelectric sheets, and each second thermoelectric sheet is partially stacked with a first thermoelectric sheet correspondingly.

14. The electronic device of claim 13, wherein the conductive member is made of an anisotropic conductive adhesive film, and is conductive only in a direction perpendicularly to the first thermoelectric sheet or the second thermoelectric sheet.

15. The electronic device of claim 13, wherein each first thermoelectric sheet comprises a first connection end, each second thermoelectric sheet comprises a second connection end and a body extending from the second connection end, the second connection end is placed below the first connection end, the body is deviated from the central processing unit, and the conductive member is sandwiched between the first connection end and the second connection end.

16. The electronic device of claim 15, wherein each first thermoelectric sheet further comprises a body extending from the first connection end, the thermoelectric cell module further comprises a heat resisting sheet, and the heat resisting sheet is sandwiched between the body of the first thermoelectric sheet and the bottom housing, and is adjacent to the second connection end.

17. The electronic device of claim 11, wherein the first thermoelectric sheet is made of antimony telluride P-type semi-conductive thermoelectric materials, and the second thermoelectric sheet is made of bismuth telluride N-type semi-conductive thermoelectric materials.

18. An electronic device, comprising:
a bottom housing;
a heat-generating component placed on the bottom housing;
a thermoelectric cell module placed on the bottom housing and corresponding to the heat-generating component, the thermoelectric cell module comprising a first thermoelectric film formed on the heat-generating component for sensing a temperature of the heat-generating component, a second thermoelectric film formed on the bottom housing for sensing a temperature of the bottom housing, and a conductive member electrically connecting the first thermoelectric film and the second thermoelectric film.

19. The electronic device of claim 18, wherein the first thermoelectric film and the second thermoelectric film are formed by magnetron sputtering, vacuum deposition, or pulsed laser deposition.

20. The electronic device of claim 18, wherein the heat-generating component comprises a central processing unit or a battery.
